(19) United States
(12) Patent Application Publication
(10) Pub. No.: US 2013/0219872 A1
(43) Pub. Date: Aug. 29, 2013

(54) THERMOELECTRIC RECOVERY AND PELTIER HEATING OF ENGINE FLUIDS

(71) Applicants: John Gibble, Greencastle, PA (US); Samuel Mclaughlin, Mercersburg, PA (US)

(72) Inventors: John Gibble, Greencastle, PA (US); Samuel Mclaughlin, Mercersburg, PA (US)

(73) Assignee: MACK TRUCKS ,INC., Greensboro, NC (US)

(21) Appl. No.: 13/883,585

(22) PCT Filed: Nov. 7, 2011
(86) PCT No.: PCT/US2011/059592

§ 371 Date: May 6, 2013

Related U.S. Application Data
(60) Provisional application No. 61/410,653, filed on Nov. 5, 2010.

(30) Foreign Application Priority Data
Jul. 14, 2011 (US) PCT US2011 043994

(51) Int. Cl. F01N 5/02; H01L 35/30

(52) U.S. Cl. CPC F01N 5/025; H01L 35/30
USPC 60/320; 136/205

(57) ABSTRACT

A waste heat recovery apparatus and process for use with an internal combustion engine includes a thermo electric apparatus that connects to components of the internal combustion engine to transfer heat between components, generate electric energy from heat extracted from components needing cooling, and convert electric energy to heat energy to transfer to components needing heating.

This application claims the benefit of U.S. Provisional Application No. 61/410,653, filed Nov. 5, 2010, and International Application No. PCT/US2011/043994, filed Jul. 14, 2011.

### FIELD OF THE INVENTION

The invention relates to Waste Heat Recovery (WHR) systems coupled with internal combustion engines. More particularly, the invention is directed to a waste heat recovery and management system including a thermoelectric device that acts as a “thermal hub” to assist heating and cooling various engine and vehicle components and systems by transferring heat between such components and systems, by converting heat to electrical energy, and converting stored electrical energy to heat.

### BACKGROUND AND SUMMARY

Waste heat recovery systems integrated with internal combustion engines can make available for use heat energy in exhaust gases and other subsystems that would otherwise be lost. When incorporated in a vehicle with an internal combustion engine, waste heat recovery systems add certain advantages beyond the recovery of energy from the exhaust. For example, the waste heat recovery system can be designed to recover heat from the EGR (exhaust gas recirculation) system, which reduces the cooling load on the engine cooling system.

The invention provides a method and apparatus for improving the recovery of waste heat from an internal combustion engine. The recovery of additional energy improves efficiency of the system as a whole.

The invention includes a thermoelectric device, which can operated as an electric generator or a heating device, coupled with an internal combustion engine apparatus. According to the described embodiment, the internal combustion engine includes a waste heat recovery apparatus. The thermoelectric device acts as an energy hub, transferring energy between devices that require heat rejection to devices requiring energy addition. The invention can thus reduce the cooling load on certain devices while it uses the recovered heat in other devices.

A waste heat recovery apparatus for an internal combustion engine may include a working fluid circuit on which are connected an expander for converting heat energy to mechanical or electrical energy, a condenser, a pump for moving the working fluid through the circuit, and a first heat exchanger for transferring heat from the internal combustion engine exhaust and/or other waste heat sources to the working fluid.

According to an embodiment, the invention relates to an apparatus and method for thawing the working fluid in such a system in the event it freezes under ambient conditions when the engine is not running. More particularly, a thermoelectric generator connected to the waste heat recovery apparatus to convert some heat energy to electric energy and may be selectively operated to convert stored electric energy to heat to thaw the working fluid.

According to the invention, the working fluid circuit includes a second heat exchanger operatively connected to an exhaust gas recirculation cooler to transfer heat to the working fluid from the exhaust gas being recirculated to the engine air intake.

In the description of the invention, the apparatus and method are described in connection with an internal combustion engine having a Rankine cycle waste heat recovery apparatus, but it should be understood that the invention applies to other waste heat recovery or recuperation devices.

According to the invention, a Thermo Electric Device (TED) is incorporated in the waste heat recovery (WHR) apparatus to act as a thermal hub for a system including the internal combustion engine, vehicle heat generating and consuming components, and the waste heat recovery apparatus. A TED in accordance with the invention includes a thermoelectric generator and an electric energy storage device, such as a battery. The TED may also be connected to deliver to one or more electric energy consuming devices. The thermoelectric generator may be operated to generate electric energy from heat for storage in the battery or run in reverse to generate heat from electric energy provided by the battery. With a TED as an energy hub, energy can be removed or added from multiple subsystems depending on the conditions and requirements of the subsystems. Heat quality will vary among the subsystems, but heavy producers are the engine exhaust, the exhaust gas recirculation (EGR) system, the charge air cooler (CAC), and the WHR system. A TED energy hub can act to recover heat from a subsystem, or use stored electrical energy to provide heat to other subsystems. Other thermal management strategies now become significantly lower on a cost/benefit ratio investigation.

The TED energy hub can advantageously provide heat to the passenger compartment while the engine warms up by converting electrical energy to heat. Additionally, the TED can heat or cool a passenger/sleeper compartment while in “hotel mode”, that is, when the vehicle is parked and the engine is off. If necessary to assist the TED, a small heater fired by fuel (natural gas, gasoline, diesel, any or all) can be provided as an additional heat source to be used either during warm up or for electrical generation during hotel mode.

The TED can also provide heat to various subsystems that may benefit from heating as during a cold start of the engine after a period of time at relatively low ambient temperatures.

A particular application of the TED thermal hub is the problem of the WHR system working fluid freezing, such as in vehicles exposed to seasonal low ambient temperatures when not running, which may occur when parked outside overnight on a cold night.

The invention solves the problem of freezing by providing a method and apparatus for starting up the waste heat recovery system with frozen working fluid and thawing the working fluid. According to the invention, the thermoelectric generator is operated in reverse, that is, as a heat generator to convert stored electric energy to heat, to thaw the working fluid when needed.

In the description of the invention, the apparatus and method are described in connection with a Rankine cycle waste heat recovery apparatus, but it should be understood that the invention applies to any waste heat recovery or recuperation device using a working fluid.

Advantageously, the apparatus and method for thawing a waste heat recovery system working fluid according to the invention decreases the time needed to start up a system with frozen working fluid, which increases the time during which heat recovery is operable. The improvement helps systems having an EGR heat exchanger meet emissions regulations by better meeting the time requirements to start the EGR system after vehicle start up.

### BRIEF DESCRIPTION OF THE DRAWINGS

The invention will be better understood by reference to the following detailed description read in conjunction with the appended drawings, in which:

FIG. 1 is a system diagram of a thermo-electric device as a thermal hub according to the invention;

FIG. 2 is a schematic of an embodiment of a waste heat recovery apparatus including a Thermo-Electric apparatus according to the invention; and,

FIG. 3 is a schematic of a Thermo-Electric system integrated with various components of an internal combustion engine and waste heat recovery apparatus according to the invention.

### DETAILED DESCRIPTION OF THE INVENTION

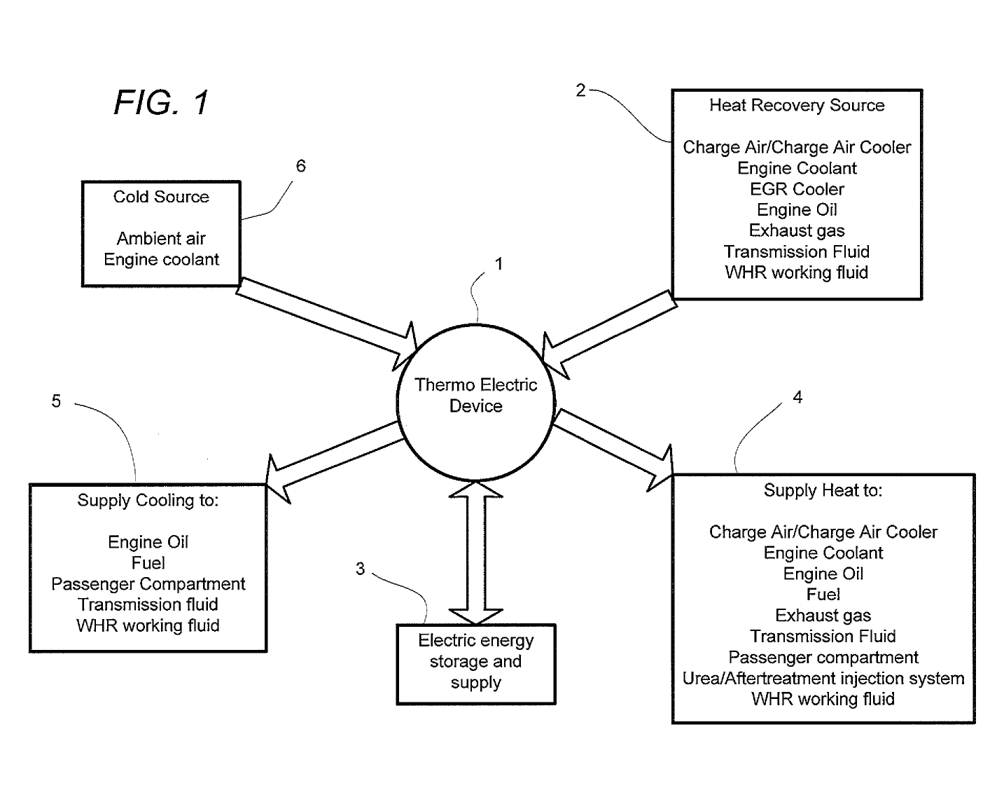

As shown schematically in FIG. 1, the invention includes a Thermo Electric Device (TED) 1 incorporated in a vehicle with an internal combustion engine and a waste heat recovery (WHR) apparatus. The TED acts as a thermal hub for the internal combustion engine and subsystems or components, vehicle heat generating and consuming components, and the waste heat recovery apparatus. With a TED as an energy hub, energy can be removed from or added to one or inure subsystems depending on the thermal status of the subsystems, that is, the thermal conditions and heat rejection or addition requirements of the subsystems. Heat quality will vary among the subsystems, but heavy producers are the engine exhaust, the exhaust gas recirculation (EGR) system, the charge air cooler (CAC), and the WHR system. A TED energy hub can act to recover heat from one or more subsystems 2, or use stored electrical energy to provide heat to other subsystems 3. Other thermal management strategies now become significantly lower on a cost/benefit ratio investigation.

The TED can act to remove and recover heat from the heat generating subsystems 2, for example, the charge air cooler (CAC), engine coolant subsystem, exhaust gas recirculation cooler, engine oil subsystem, engine oil subsystem, engine exhaust flow, transmission fluid subsystem, and the WHR working fluid, for example. The TED can store recovered energy as electrical energy in a storage device 3, for example, a battery. Alternatively, or in addition, the TED can deliver electric energy directly to energy consuming devices on the vehicle.

The TED can also provide heat to various subsystems that may benefit from heating as, for example, a cold start of the engine after a period of time at relatively low ambient temperatures. The heat receiving subsystems 4 may include the charge air cooler (CAC), engine coolant subsystem, exhaust gas recirculation cooler, engine oil subsystem, fuel system, engine oil subsystem, engine exhaust flow, transmission fluid subsystem, an exhaust gas aftertreatment injection subsystem, and the WHR working fluid, for example.

The TED energy hub can provide cooling to components requiring cooling 5, such as the engine oil subsystem, fuel system, the transmission fluid subsystem, and the WHR working fluid, which can lower the heat rejection demands on these systems.

For cold sources 6 for operation of the thermoelectric device, the TED can be operatively connected, by way of a heat exchanger, to ambient air and to the engine coolant subsystem.

In addition, the TED energy hub can advantageously provide heat to the passenger compartment while the engine warms up by converting electrical energy to heat and by way of a heat exchanger to heat the air for the passenger compartment. Additionally, the TED can heat or cool a passenger/sleeper compartment while in “hotel mode”, that is, when the vehicle is parked and the engine is off. To assist the TED, a small heater fired by fuel (natural gas, gasoline, diesel, any or all) may be provided as an additional heat source to be used either during warm up or for electrical generation during hotel mode.

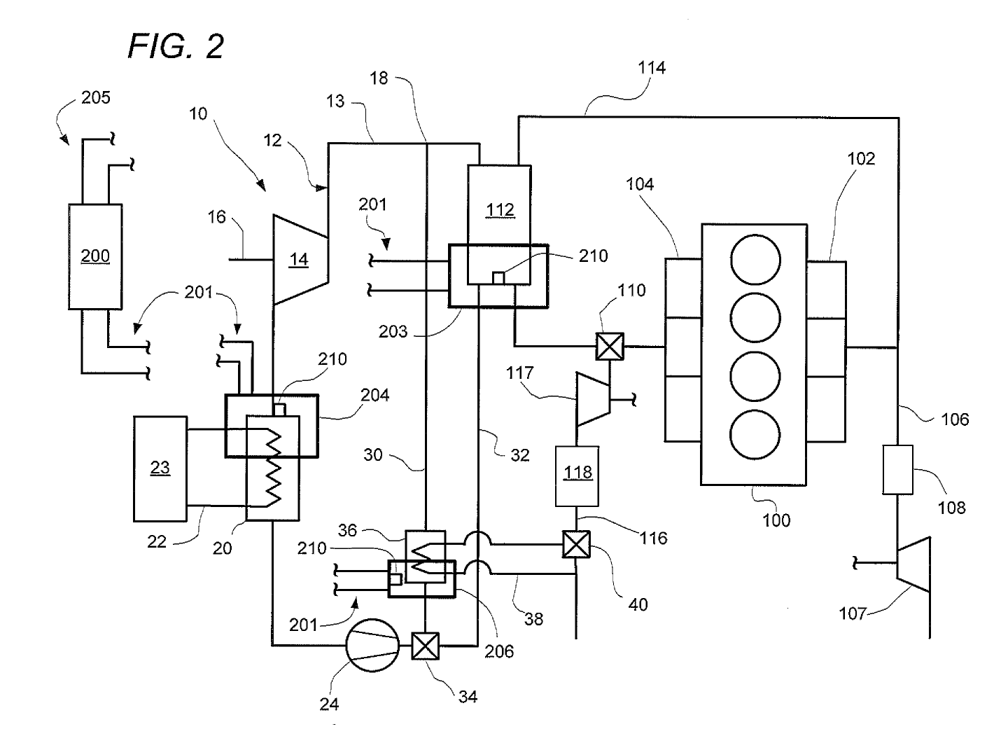

FIG. 2, below, shows as an example of an application of the invention, a thermoelectric device 200 connected as an energy hub in an internal combustion engine 100 apparatus including a Rankine cycle waste heat recovery apparatus 10. The invention is shown in conjunction with a Rankine cycle waste heat recovery apparatus, such as that described in co-owned and co-pending International Patent Application No. PCT/US2011/043994, filed Jul. 14, 2011, the disclosure of which is incorporated herein by reference. However, the embodiment shown and described is meant to be illustrative and not limiting; the invention may be applied to other waste heat recovery cycles and apparatuses, for example, an Ericsson or other bottoming cycles.

During normal operation and according to the thermal status of a component, the thermoelectric device 200 can remove heat from the bottoming cycle working fluid. Heat energy is removed from the hot source location and converted to electrical energy by the thermoelectric unit. As will be described below, alternatively, the thermoelectric device 200 can provide heat energy to components depending on the opposite thermal status, that is, whether the component requires heat addition rather than heat extraction.

The internal combustion engine 100 includes an intake manifold 102 and an exhaust manifold 104. Fresh air is supplied to the intake manifold through intake line 106, which may be supplied by a turbocompressor 107 and cooled by a charge air cooler 108, as is known in the art. A portion of the exhaust gas is recirculated to the intake manifold 102 by an exhaust gas recirculation (EGR) system including an EGR valve 110, an EGR cooler 112, and return line 114 connecting to the intake manifold.

The EGR valve 110 also controls the flow of exhaust gas to an exhaust conduit 116, for example, an exhaust stack or tailpipe, from which waste exhaust gas is released into the environment.

The internal combustion engine 100 may also include, as mentioned, an exhaust gas turbine 117 mounted on the exhaust gas conduit 116 for driving the turbocompressor 107. Other devices may be included, for example, a compound turbine driven by the exhaust gas to generate electrical energy. The internal combustion engine may also include an exhaust aftertreatment system 118 to, for example, convert NOx and/or remove particulate matter or unburned hydrocarbons from the exhaust gas before it is released to the environment.

The waste heat recovery apparatus 10, as shown in this exemplary embodiment, is a closed loop system in which a working fluid is compressed, heated by the exhaust gas, and expanded to recover heat energy.

The Rankine cycle waste heat recovery apparatus 10 as shown in this example embodiment includes a working fluid circuit 12, formed as a closed loop through which a working fluid is circulated. An expander 14 is connected on the working fluid circuit 12 to be driven by working fluid to convert heat energy in the working fluid into mechanical energy. An output shaft 16 may be connected to drive an electrical generator or connected to the provide torque to the engine. The expander 14 may be a turbine as illustrated, or a scroll expander or other device capable of recovering heat energy from a working fluid.

A condenser 20 is connected on the working fluid circuit 12 to receive working fluid that exits the expander 14. The condenser 20 cools and condenses the working fluid. A condenser cooler loop 22 is connected for carrying away from the condenser 20 heat transferred from the working fluid to a cooling fluid. The condenser cooler loop 22 may conveniently connect to the vehicle cooling system 23, i.e., the radiator, or another cooling system.

A pump 24 receives the condensed working fluid exiting the condenser 20 and pumps the working fluid to the heating side of the working fluid circuit 12 where the working fluid is heated.

The heating side of the working fluid circuit 12 includes a first heating line 30 and a second heating line 32 arranged in parallel. The first heating line 30 and second heating line 32 branch at a dividing junction on which a valve 34 is connected that controls the flow of working fluid into the heating lines. The valve 34 may direct the flow selectively into one heating line or divide the flow into both of the heating lines 30, 32, responsive to the system demands and limitations, described in more detail below. The heating lines 30, 32 rejoin at a combining junction 18 into a single line 13 that connects to an inlet of the expander 14.

The first heating line 30 is operatively connected to a boiler 36 or heat exchanger that transfers heat from waste engine exhaust gas that will be released to the environment. The exhaust gas is conducted to the boiler 36 by a loop 38 controlled by a valve 40 in the exhaust conduit 116. Alternatively, the first heating line 30 may loop into a heat exchanger connected on the exhaust gas conduit 116 to receive more of the exhaust gas heat.

The second heating line 32, parallel to the first heating line, branches at the valve 34 and is operatively connected to the EGR cooler 112 for transferring heat from the EGR gas to the working fluid. The EGR cooler 112 acts as a boiler for the working fluid in the second heating line 32. The working fluid flowing in the first heating line 30 and second heating line 32, heated by the exhaust boiler 36 and EGR cooler 112, respectively, is combined at combining junction 29 in line 13 and directed to the expander 14.

By using separate heating lines, the working fluid used for recovering heat energy from the EGR cooler 112, which cools the EGR gas, is at a lower temperature as it enters the EGR cooler than it would be if the working fluid was heated by the exhaust gases in the exhaust gas boiler 36 prior to entry in the EGR cooler. This has the advantage of more effective operation of the EGR cooler 112. Because the additionally heated working fluid is added only to the first heating line 30, and not the second heating line 32 including the EGR cooler 112, the working fluid is not overheated in the EGR cooler and the EGR cooler can more readily cool the EGR gas to the desired or target temperature for use by the engine.

The working fluid exiting the expander 14 is at a temperature significantly higher than the condensation temperature of the working fluid, for example, in the illustrated waste heat recovery apparatus it can be about 100° C. higher than the condensation temperature. This heat energy has to be removed from the working fluid, and in the apparatus of FIG. 2, the heat load is transferred in part to the condenser heat exchanger loop 22 and in part to the thermoelectric device 200, as described below.

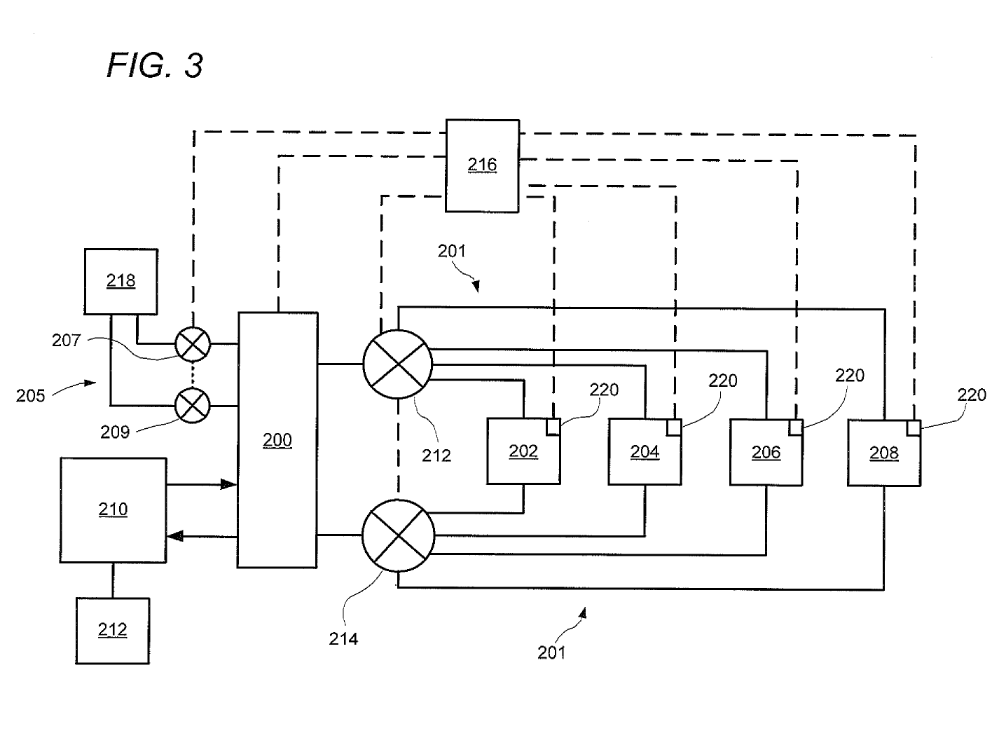

The thermoelectric device 200, including a thermoelectric generator and electrical energy storage (e.g., a battery), is integrated with the waste heat recovery system 10 to convert some of the heat energy to electrical energy. The thermoelectric device 200 is connected by a flow circuit 205 to circulate a TED cold side working fluid to a cold source, which may include a heat exchanger. The cold source may be ambient air or the engine coolant system. The thermoelectric device 200 is also connected by way of circuit 201 with a first heat exchanger 202 to extract heat from the EGR cooler 112, a second heat exchanger 204 to extract heat from the condenser 20, and a third heat exchanger 206 to extract heat from the downstream exhaust heat exchanger 36. The thermoelectric device circuit 201 may include conduits forming individual loops between the heat exchangers and the thermoelectric device as shown in FIG. 3. A thermoelectric device hot side working fluid circulates between the first 202, second 204, and third 206 heat exchangers and the thermoelectric device 200. The heat exchangers may be series flow heat exchangers, counterflow heat exchangers or other arrangements. The TED heat exchangers are positioned at the portion of the WHR heat exchanger where temperature difference is a maximum, that is, where the non-working fluid (the fluid from which heat is extracted) is hottest and the working fluid is coldest. If the maximum temperature of the non-working fluid side is too high, the TED heat exchanger could be moved downstream of the maximum temperature differential location, that is, at a midpoint of the companion WHR heat exchanger or downstream of it.

Alternatively, the WHR system could be one that does not incorporate an expansion device 14 at all. As TEG and battery technology develops and improves, the WHR system could be replaced by a standard TEG WHR system, sized large enough to handle the entire WHR system heat rejection requirements.

An advantage of the invention is that the additional heat removed by the TED 200 from at least one of the EGR cooler 112 and the condenser 20 lowers the engine coolant system requirements, as both these devices may be connected also the engine coolant system.

Charge air coolers and engine exhaust coolers are typically counter flow heat exchangers, which by design have the highest temperature fluid exiting the exchanger at the entrance location of the fluid being cooled, which is preferably where the TED heat exchangers are located. The heat exchange design may cause the WHR working fluid to deteriorate if the temperature of the fluid or lubricant in the fluid is too high. This is of particular concern if the working fluid in a waste heat recovery system enters superheating, where temperature increases are very sensitive to the addition of energy. Also of concern during superheating situations where the working fluid is totally evaporated is the sharp decline in heat transfer coefficient, and resulting sharp increase in wall temperature in the heat exchanger itself. The thermal cycling of the heat exchanger and the large temperature gradient that exists in the wall material will damage the cooler. Removal of heat using the TED helps avoid or lessen these problems. The invention reduces coolant demand and increases waste heat recovery, which improves system efficiency.

Extended cold temperature exposure of the WHR system may lead to the working fluid freezing. A working fluid in a heat exchanger normally transfers heat to itself by forced convection across the heat exchanger fin or tube, which itself is receiving heat from forced convection from the fluid being cooled (e.g., charge air, exhaust). When the working fluid enters freezing conditions, this normally efficient heat transfer is not possible and heat must pass by conduction and natural convection. Under these conditions, the fluid will take a significant time to thaw.

According to the invention, by applying voltage to the thermoelectric device 200, the device generates heat, creating a temperature gradient that will heat and thaw the working fluid. Thus, the TED 200 heat exchanger 204 can heat the WHR working fluid in the condenser 20 to an operative working temperature. Such heat transfer can be also effected by way of the heat exchanger 202 connected to the EGR cooler 112. This significantly reduces warm-up time, allowing the engine system to more quickly meet emissions regulations and reduces the risk of component or fluid damage due to the thermal conditions.

An additional benefit of adding thermoelectric recovery to the working fluids of an engine is that heat can be extracted without adding restrictions to the air pumping circuit (intake or exhaust), which are fuel economy sensitive functions.

Turning to FIG. 3, a thermoelectric device system in accordance with the invention includes the thermoelectric generator 200, and a storage device 210 for electric energy, such as a battery. The battery 210 may be connected to an energy consuming vehicle device 212 as a source of electric energy for that device. Alternatively, or in addition, the thermoelectric generator 200 may be connected directly to the energy consuming device 212. The TED is connected to a cold source 218 by the cold side circuit 205, which includes valves 207, 209 to control the flow in the cold side circuit. The TED system includes valves 212, 214 to control the flow of the thermoelectric apparatus working fluid between the thermoelectric generator 200 and the one or more heat exchangers 203, 204, 206 and 208 by way of the circuits 201. A controller 216 is connected to receive temperature data from sensors 220 positioned to sense or determine the WHR working fluid thermal status. The temperature sensors 220 are shown in FIG. 3 as being positioned with the thermoelectric apparatus heat exchangers 202, 204, 206, and 208, as these heat exchangers are in thermal contact with the WHR working fluid and the engine subsystems. The controller 210 determines whether the WHR working fluid requires heat extraction or requires heat addition to control the valves on the condenser coolant loop 22. The controller 210 also controls the working fluid pump 24 for operation when the WHR working fluid is sufficiently thawed or otherwise at a temperature at which it can be pumped.

Heat exchangers for thermoelectric recovery may be located where heat is available for recovery or heat is needed for addition. In addition to the EGR cooler heat exchanger 202, the WHR condenser heat exchanger 204, and the exhaust tail pipe heat exchanger 206, it is possible to locate a heat exchanger 208 at one or more of the charge air cooler 108, or transmission cooler, for example. The heat exchanger may act as a pre-heater, boiler, or super-heater in bottoming cycle waste heat recovery systems.

The TED 200 can advantageously provide heat to the passenger compartment while the engine warms up by providing a heat exchanger 208 for heating the air for the passenger compartment. Alternatively, the TED apparatus 200 can be connected to deliver electric energy to operate a heating device, such as an electric resistance heater. Additionally, using the electric energy stored in the battery storage system 205, the TED 200 can operate an air conditioning unit 212 to heat or cool a passenger/sleeper compartment while in “hotel mode”, that is, when the vehicle is parked and the engine is off.

Many configurations of waste heat recovery systems are possible. Series, parallel, or combined series-parallel systems can extract heat from several sources, including EGR, exhaust gas, charge air, oil, or any other heat source on the vehicle. Several bottoming cycles also exist. The example shown is for a parallel Rankine cycle, but the invention can be applied to any heat exchanger.

The invention has been described in terms of preferred principles, embodiments, and componentry; however, those skilled in the art will understand that some substitutions may be made without departing from the scope of the invention as defined by the appended claims.

1. A thermo electric apparatus for a vehicle having an internal combustion engine, comprising:
a thermo electric device, including a thermo electric generator for selectively generating electric energy from heat energy extracted from a working fluid and selectively converting electric energy to heat energy to heat the working fluid;
a battery connected to the thermo electric device for storing electric energy generated by the thermo electric device and for providing electric energy to the thermoelectric device;
a working fluid circuit connected to the thermo electric device and including heat exchangers connected to transfer heat between the working fluid and internal combustion engine components; and,
a controller, responsive to the thermal status of at least one component, for controlling the thermo electric device to heat the working fluid to provide heat to the at least one component or generate electric energy from heated working fluid received from the at least one component.

2. The thermo electric apparatus as claimed in claim 1, wherein the internal combustion engine includes a waste heat recovery apparatus, and wherein the thermo electric apparatus working fluid circuit includes heat exchangers operatively connected to components of the waste heat recovery apparatus to transfer heat between the components and the thermo electric working fluid circuit.

3. The thermo electric apparatus of claim 2, wherein the waste heat recovery apparatus is a closed cycle system having an expander and a condenser, and wherein the thermo electric apparatus working fluid circuit includes a heat exchanger operatively connected to the condenser to transfer heat energy selectively to and from the condenser.

4. The thermo electric apparatus of claim 2, wherein the waste heat recovery apparatus includes a heat exchanger operatively connected to transfer heat energy to a waste heat recovery apparatus working fluid from a waste exhaust gas flow of an internal combustion engine, and wherein the thermo electric apparatus includes a heat exchanger to transfer heat energy between the waste gas flow and the thermo electric apparatus.

5. The thermo electric apparatus of claim 2, wherein the waste heat recovery apparatus includes a heat exchanger operatively connected to transfer heat energy to the waste heat recovery apparatus working fluid from an exhaust gas recirculation cooler of an internal combustion engine, and wherein the thermo electric apparatus includes a heat exchanger the transfer heat energy from the exhaust gas recirculation cooler to the thermo electric apparatus.

6. The thermo electric apparatus as claimed in claim 1, wherein the thermo electric apparatus is operatively connected to extract heat from at least one of a charge air cooler, an engine coolant system, an exhaust gas recirculation system cooler, an engine oil system, an exhaust gas flow, a transmission fluid system, and a waste heat recovery apparatus working fluid circuit.

7. The thermo electric apparatus as claimed in claim 1, wherein the thermo electric apparatus is operatively connected to supply heat energy to at least one of a charge air cooler, an engine coolant system, an engine oil system, an exhaust gas flow, a transmission fluid system, a vehicle passenger compartment, an exhaust aftertreatment injection system, and a waste heat recovery apparatus working fluid system.

8. An internal combustion engine apparatus, comprising:
a waste heat recovery apparatus including heat exchangers to recover heat from at least one of an engine exhaust flow and an exhaust gas recirculation cooler;
a thermo electric device, including a thermo electric generator for selectively generating electric energy from heat energy extracted from a working fluid and selectively converting electric energy to heat energy to heat the working fluid;
a battery connected to the thermo electric device for storing electric energy generated by the thermo electric device and for providing electric energy to the thermoelectric device;
a working fluid circuit connected to the thermo electric device and including heat exchangers connected to transfer heat between the working fluid and at least one of the engine exhaust flow and the exhaust gas recirculation cooler; and,
a controller, responsive to the thermal status of at least one component, for controlling the thermo electric device to heat the working fluid or generate electric energy from heated working fluid received from at least one of the engine exhaust flow and the exhaust gas recirculation cooler.

9. The thermo electric apparatus of claim 8, wherein the waste heat recovery apparatus is a closed cycle system having an expander and a condenser, and wherein the thermo electric apparatus working fluid circuit includes a heat exchanger operatively connected to the condenser to transfer heat energy selectively to and from the condenser.
